(19) United States
(12) Patent Application Publication
(10) Pub. No.: US 2026/0180366 A1
(43) Pub. Date: Jun. 25, 2026

(54) INFORMATION PROCESSING DEVICE

(71) Applicant: TDK Corporation, Tokyo (JP)

(72) Inventor: Keita SUDA, Tokyo (JP)

(73) Assignee: TDK Corporation, Tokyo (JP)

(21) Appl. No.: 18/850,281

(22) PCT Filed: Mar. 25, 2022
(86) PCT No.: PCT/JP2022/014722

§ 371 Date: Sep. 24, 2024

(51) Int. Cl. H02J 50/12; G06F 30/33; H02J 50/10

(52) U.S. Cl. CPC H02J 50/12; G06F 30/33; H02J 50/10

(57) ABSTRACT

An information processing device includes a plurality of magnetic circuits, at least one input terminal that is connected to at least one of the plurality of magnetic circuits, at least one output terminal that is connected to at least one of the plurality of magnetic circuits, and at least one connection portion that electrically or magnetically couples at least two of the plurality of magnetic circuits.

### TECHNICAL FIELD

The present invention relates to an information processing device.

### BACKGROUND ART

In recent years, edge computing, which processes data in a distributed manner, has been attracting attention. Edge computing is a concept that opposes cloud computing, which processes data centrally in a cloud. Edge computing has characteristics that it does not require a large-scale server like cloud computing, can reduce a network load, and makes it easy to strengthen security.

Reservoir computing is expected to be used on edge terminals that handle edge computing. Reservoir computing is a type of neural network that, for example, emulates an operation of a cerebellum. Reservoir computing performs recursive processing by interacting with signals.

Development of neural networks using software is in progress, but the calculation load may be high and sufficient processing efficiency may not be achieved. For this reason, devices that emulate neural networks using hardware have been proposed. A reservoir device is a device specialized for reservoir computing. A reservoir device described in Patent Document 1 interacts with signals using spin waves propagating through wiring. A reservoir device described in Non-Patent Document 1 uses spin waves to cause signals to interact with each other.

### CITATION LIST

### Patent Document

Patent Document 1: PCT International Publication No. WO2020/105136

### Non Patent Document

Non Patent Document 1: Ryosho Nakane, Gouhei Tanaka, and Akira Hirose, IEEE Access Vol. 6 2018 pp. 4462-4469

### SUMMARY OF INVENTION

### Technical Problem

Each reservoir device has its advantages and disadvantages. A breakthrough in the development of reservoir devices requires consideration of a new reservoir device.

The present invention has been made in consideration of the circumstances described above, and aims to provide an information processing device that can emulate reservoir computing with a new configuration.

### Solution to Problem

(1) An information processing device according to a first aspect includes a plurality of magnetic circuits, at least one input terminal that is connected to at least one of the plurality of magnetic circuits, at least one output terminal that is connected to at least one of the plurality of magnetic circuits, and at least one connection portion that electrically or magnetically couples at least two of the plurality of magnetic circuits.

(2) In the information processing device according to the aspect described above, at least one of the plurality of magnetic circuits may have a shape different from the other magnetic circuits.

(3) In the information processing device according to the aspect described above, at least one of the plurality of magnetic circuits may have a gap in a portion of a magnetic path through which a magnetic flux circulates.

(4) In the information processing device according to the aspect described above, at least one of the plurality of magnetic circuits may be connected to a load.

(5) In the information processing device according to the aspect described above, the connection portion may include a coil wound around two or more different magnetic circuits.

6) In the information processing device according to the aspect described above, the at least one connection portion may be a plurality of connection portions, the plurality of connection portions may include a first connection portion and a second connection portion, the first connection portion and the second connection portion may each include a coil wound around two or more different magnetic circuits, and the number of turns of a coil constituting the first connection portion may be different from the number of turns of a coil constituting the second connection portion.

(7) In the information processing device according to the aspect described above, the connection portion may include a switch that switches an electrical or magnetic coupling state between at least two magnetic circuits.

(8) In the information processing device according to the aspect described above, the plurality of magnetic circuits may be arranged three-dimensionally through the connection portion.

(9) In the information processing device according to the aspect described above, the plurality of magnetic circuits may be arranged in a ring shape through the connection portion.

(10) In the information processing device according to the aspect described above, the plurality of magnetic circuits may be arranged in a line shape through the connection portion.

(11) In the information processing device according to the aspect described above, the plurality of magnetic circuits may be arranged in a tree shape through the connection portion.

(12) In the information processing device according to the aspect described above, each of the plurality of magnetic circuits may be connected to each other through one connection portion.

(13) In the information processing device according to the aspect described above, each of the plurality of magnetic circuits may be connected to all of the different magnetic circuits through the connection portion.

(14) The information processing device according to the aspect described above may further include an input layer that is connected to the input terminal, and an output layer that is connected to the output terminal.

### Advantageous Effects of Invention

The information processing device according to the aspects described above can emulate reservoir computing in a new configuration.

### BRIEF DESCRIPTION OF DRAWINGS

FIG. 1 is a conceptual schematic diagram of reservoir computing simulated by an information processing device according to a first embodiment.

FIG. 2 is a plan view of the information processing device according to the first embodiment.

FIG. 3 is a plan view of a characteristic portion of an information processing device according to a first modified example.

FIG. 4 is a plan view of a characteristic portion of an information processing device according to a second modified example.

FIG. 5 is a plan view of a characteristic portion of an information processing device according to a third modified example.

FIG. 6 is a plan view of a characteristic portion of an information processing device according to a fourth modified example.

FIG. 7 is a plan view of a characteristic portion of an information processing device according to a fifth modified example.

FIG. 8 is a plan view of a characteristic portion of an information processing device according to a sixth modified example.

FIG. 9 is a plan view of a characteristic portion of an information processing device according to a seventh modified example.

FIG. 10 is a plan view of a characteristic portion of an information processing device according to an eighth modified example.

FIG. 11 is a plan view of a characteristic portion of an information processing device according to a ninth modified example.

FIG. 12 is a plan view of a characteristic portion of an information processing device according to a tenth modified example.

FIG. 13 is a plan view of a characteristic portion of an information processing device according to an eleventh modified example.

FIG. 14 is a plan view of a characteristic portion of an information processing device according to a twelfth modified example,

FIG. 15 is a plan view of a magnetic circuit according to a thirteenth modified example.

FIG. 16 is a plan view of a magnetic circuit according to a fourteenth modified example.

FIG. 17 is a plan view of a characteristic portion of an information processing device according to a fifteenth modified example.

### DESCRIPTION OF EMBODIMENTS

Hereinafter, the present embodiment will be described in detail with reference to the drawings as appropriate. The drawings used in the following description may show enlarged parts which are characteristics for a sake of convenience to make the characteristics of the present invention easier to understand, and dimensional ratios of each component may differ from the actual ones. Materials, dimensions, and the like exemplified in the following description are merely examples, and the present invention is not limited to these. They can be modified as appropriate within a scope of effects of the present invention.

First, directions are defined. A surface on which the magnetic circuit 1 extends is set to an xy plane, one direction thereof is set to an x direction, and a direction orthogonal to the x direction is set to a y direction. A direction orthogonal to the x and y directions is set to a z direction.

### First Embodiment

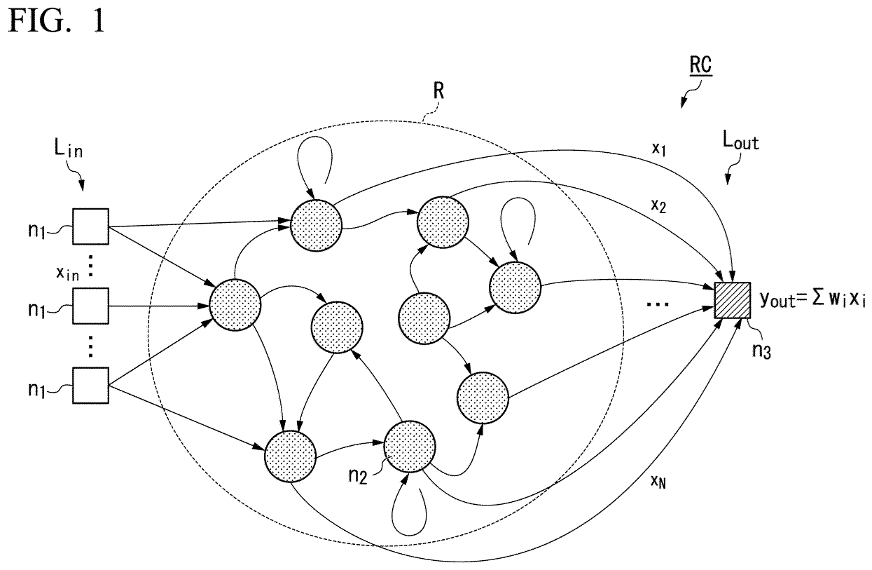

The information processing device according to a first embodiment is a device that emulates reservoir computing. FIG. 1 is a conceptual schematic diagram of reservoir computing RC that is simulated by the information processing device according to the first embodiment. First, reservoir computing RC will be described.

Reservoir computing RC is one means for realizing a neural network that emulates a human brain. The reservoir computing RC performs recursive processing by causing signals to interact with each other. The reservoir computing RC emulates, for example, an operation of the cerebellum, and performs recursive data processing and data transformation (for example, coordinate transformation). The reservoir computing RC is one aspect of a recurrent neural network that can handle nonlinear time series data. Nonlinear time series data is data whose value changes over time, and stock prices are one example.

The reservoir computing RC has an input layer Lᵢₙ, a reservoir R, and an output layer Lₒᵤₜ. The input layer Lᵢₙ is connected to the reservoir R. The output layer Lₒᵤₜ is connected to the reservoir R.

The input layer Lᵢₙ is, for example, a single-layer or multi-layer perceptron. The input layer Lᵢₙ has, for example, a plurality of nodes n₁. The input layer Lᵢₙ transmits signals input from the outside to the reservoir R. An input signal input from the outside to a node n₁ of the input layer Lᵢₙ is transmitted to the reservoir R.

An input signal is input to the reservoir R from the input layer Lᵢₙ. The reservoir R stores input signals that are input and is an area where the input signals interact with each other. The reservoir R has a plurality of nodes n₂ that are randomly connected to each other.

In the reservoir R, signals only interact with each other, and they do not learn from each other. When signals interact with each other in the reservoir R, the input signals change nonlinearly. Furthermore, the input signals change over time as they interact with each other in the reservoir R. In addition, in the reservoir R, a signal output from a node n₂ at a certain time t may return to the original node n₂ at a certain time t+1. In other words, the node n₂ can process signals at times t and t+1, and can process information recursively. Therefore, the reservoir R can process time-series signals.

The output layer Lom detects a signal from the reservoir R. The output layer Lₒᵤₜ includes, for example, a node n₃. Learning is performed in pathways (synapses in a brain) that connect each node n₂ in the reservoir R to the node n₃ in the output layer Lₒᵤₜ. The output layer Lₒᵤₜ outputs a result of learning to the outside. The output layer Lₒᵤₜ multiplies a signal xᵢ from each node n₂ by a weight wᵢ, and adds up results of each multiplication. The output layer Lₒᵤₜ may have an activation function. A result of the multiplication and addition is input to the activation function.

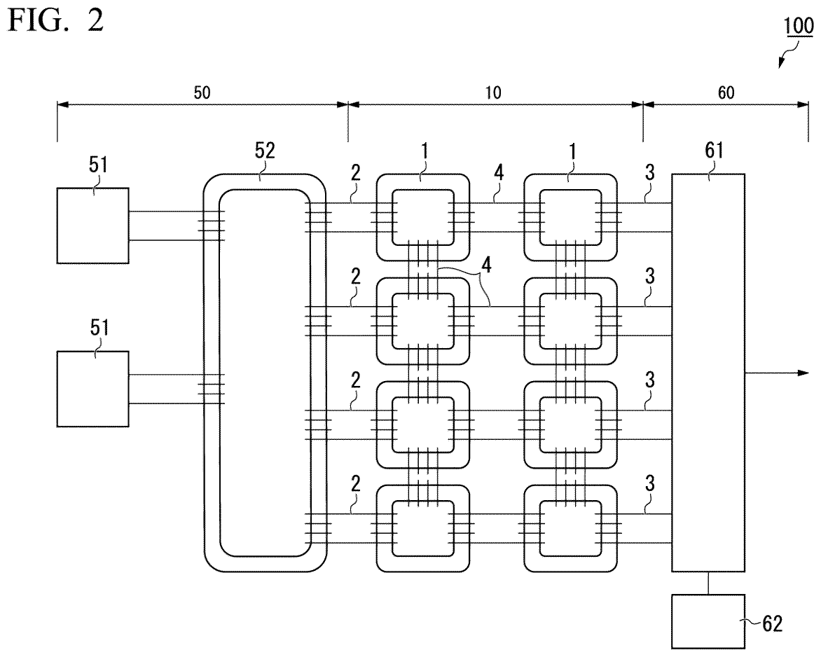

FIG. 2 is a plan view of the information processing device 100 according to the first embodiment. The information processing device 100 performs the same operation as the reservoir computing RC. Most of the information processing device 100 is made up of passive components, and in the case of software, power consumption associated with calculation of the reservoir computing RC can be reduced.

The information processing device 100 has, for example, a reservoir 10, an input layer 50, and an output layer 60.

The input layer 50 has an input source 51 and a signal distribution unit 52. The input layer 50 corresponds to the input layer Lᵢₙ of the reservoir computing RC.

The input source 51 is, for example, a voltage source, a current source, a sensor, or the like. Input signals from the input source 51 are, for example, time series signals. The time series signals are, for example, divided into time domains and input to the signal distribution unit 52 as a plurality of signals. The input signals may be input as they are without processing, or the signals may be input after Fast Fourier Transform Analysis (FFT analysis). The FFT analysis extracts frequency characteristics. In addition, the FFT analysis can filter signals with small amplitudes caused by noise.

The signal distribution unit 52 distributes one common signal to several magnetic circuits 1 of the reservoir 10. The signal distribution unit 52 shown in FIG. 2 is a magnetic circuit, and inputs a common magnetic flux as a signal to a plurality of magnetic circuits 1 of the reservoir 10. Here, an example has been shown in which the signal distribution unit 52 distributes a common magnetic flux, but it may also distribute a common voltage, current, and the like. When the signal distribution unit 52 distributes a voltage, the plurality of magnetic circuits 1 are connected in parallel with wiring. When the signal distribution unit 52 distributes a current, the plurality of magnetic circuits 1 are connected in series with wiring.

The output layer 60 has an arithmetic unit 61 and a memory 62. The output layer 60 corresponds to the output layer Lot of the reservoir computing RC.

The arithmetic unit 61 has, for example, a detection circuit, a processor, and a register. In the arithmetic unit 61, the processor executes a program recorded in the register. The detection circuit detects, for example, a result of the multiplication and addition by adding together results of the multiplication in which a connection weight wᵢ is applied to the signal xᵢ. The arithmetic unit 61 also performs a calculation to substitute the result of the multiplication and addition into an activation function. The connection weight wᵢ is updated in a learning stage, and the information processing device 100 performs inference on the basis of the updated connection weight wᵢ. The memory 62 stores, for example, the connection weight wᵢ.

The reservoir 10 includes a magnetic circuit 1, an input terminal 2, an output terminal 3, and a connection portion 4.

There are a plurality of magnetic circuits 1. The magnetic circuit 1 is a closed circuit through which a magnetic flux circulates. The magnetic circuit 1 is, for example, a ferromagnetic material such as iron. The magnetic flux circulates along a ring-shaped ferromagnetic material. The number of magnetic circuits 1 is not important, but as the number of magnetic circuits 1 increases, expression power of the reservoir 10 is enhanced.

The input terminal 2 is connected to the input layer 50. There is at least one input terminal 2. The input terminal 2 is connected to at least one of the plurality of magnetic circuits 1. When there are a plurality of input terminals 2, each input terminal 2 is connected to, for example, a different magnetic circuit 1. The input terminal 2 is, for example, a coil. When an input signal flows as a current through the coil, a magnetic field is generated inside the coil, and a magnetic flux returns in the magnetic circuit 1.

The output terminal 3 is connected to the output layer 60. There is at least one output terminal 3. The output terminal 3 is connected to at least one of the plurality of magnetic circuits 1. When there are a plurality output terminals 3, each output terminal 3 is connected to, for example, a different magnetic circuit 1. The output terminal 3 is; for example, a coil. A current is induced in the output terminal 3 by electromagnetic induction of the magnetic field generated in the magnetic circuit 1.

The connection portion 4 electrically or magnetically couples at least two of the plurality of magnetic circuits 1. It is arbitrary which magnetic circuits 1 are connected to each other by the connection portion 4. For example, the connection state of the connection portion 4 may be changed according to a task. The connection portion 4 is, for example, a coil. The magnetic flux circulating within the magnetic circuit 1 induces a current in the connection portion 4, and the current flowing through the connection portion 4 applies a magnetic field to another magnetic circuit 1.

Next, an operation of the information processing device 100 will be described.

First, a signal generated by the input source 51 is distributed by the signal distribution unit 52, and a common input signal is input to the plurality of magnetic circuits 1 in the reservoir 10. This processing corresponds to an input of an input signal from the input layer Lᵢₙ to the reservoir R in the reservoir computing RC.

The input signal is applied to the magnetic circuit 1 from the input terminal 2. The input signal is applied to the magnetic circuit 1 as, for example, a magnetic field.

The input signal applied to the magnetic circuit 1 propagates like a wave through the reservoir 10 through the connection portion 4. Input signals interact with each other through the connection portion 4. For example, a magnetic field generated in one magnetic circuit 1 affects other magnetic circuits 1. Each magnetic circuit 1 has, for example, hysteresis of a magnetic material that constitutes the magnetic circuit 1, a signal delay due to the coil, and the like, and performs nonlinear transformation of a signal. The input signal propagates between the magnetic circuits 1 while nonlinear transformation is performed.

The reservoir 10 projects an input signal input from the input terminal 2 into a multidimensional nonlinear space. By propagating the input signal between a plurality of magnetic circuits 1 through the connection portion 4, the reservoir 10 generates a characteristic space containing information of the input signal. This processing corresponds to the processing in the reservoir R in the reservoir computing RC.

The output terminal 3 outputs an output signal to the output layer 60. The output signal may be, for example, a magnetic field, a voltage, or a current. For example, a current is induced in the output terminal 3 by electromagnetic induction of a magnetic field generated in the magnetic circuit 1, and the current is output. The processing corresponds to an output of an output signal from the reservoir R to the output layer Lₒᵤₜ in the reservoir computing RC.

The connection weight wᵢ is set between the reservoir R and the output layer Lₒᵤₜ in the reservoir computing RC. The connection weight w; can be adjusted by, for example, the number of turns of a coil constituting the output terminal 3, a turning direction of the coil, a thickness of the coil, a length of the coil, a material of the coil, and the like. For example, positive or negative of the connection weight wᵢ can be changed by changing the turning direction of the coil.

The arithmetic unit 61 performs multiplication and addition on a signal output from the output terminal 3. The information processing device 100 outputs a response to a task based on a result of the multiplication and addition.

As described above, the information processing device 100 according to the first embodiment realizes a concept of the reservoir computing RC as a device. When the reservoir computing RC is realized using software, sufficient processing efficiency may not be obtained due to an influence of a calculation processing speed, or the like. In contrast, the information processing device 100 according to the first embodiment embodies the concept of the reservoir computing RC using a physical phenomenon, and therefore can achieve high processing efficiency without being influenced by the calculation processing speed, or the like.

The present invention has been described above in detail using the information processing device 100 according to the first embodiment as an example, but the configuration of the information processing device 100 is not limited to these embodiments and various modifications and changes are possible.

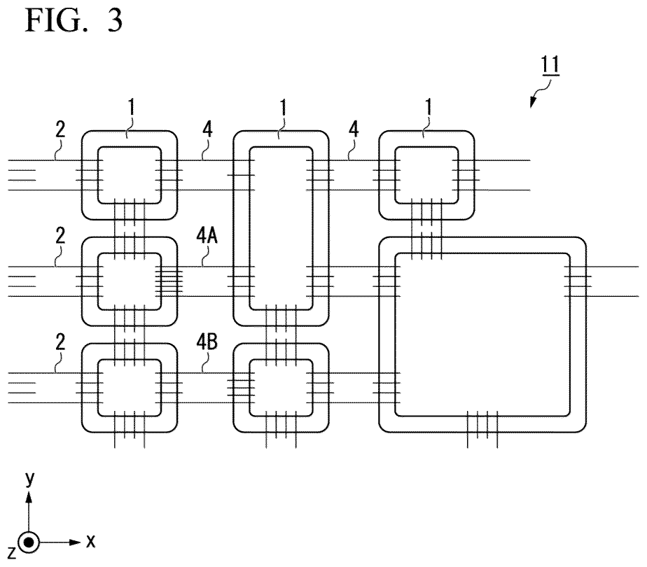

FIG. 3 is a plan view of the reservoir 11 according to a first modified example. In the reservoir 11 shown in FIG. 3, the same configuration as that of the reservoir 10 will not be described.

At least one of the plurality of magnetic circuits 1 has a different shape from the other magnetic circuits 1. The shape is, for example, a length, a cross-sectional area, a planar shape, or the like of the magnetic material constituting the magnetic circuit 1. For example, as shown in FIG. 3, a size of the magnetic circuit 1 in a planar view does not have to be constant. When there is a variation in a shape of the magnetic circuit 1, nonlinearity of the signal transformation in the reservoir 11 increases, and the expression power of the reservoir 11 is enhanced.

Moreover, in the reservoir 11, a state of the connection portion 4 varies depending on a location. For example, the number of turns of coil constituting a first connection portion 4A differs from the number of turns of coil constituting a second connection portion 4B. Here, an example is shown in which the state of the connection portion 4 is changed by the number of turns of a coil, but the present invention is not limited to this example, and the state of the connection portion 4 may be changed by a cross-sectional area of the coil, a length of the coil, a material of the coil, and the like. When there is variation in the state of the connection portion 4, the nonlinearity of the signal transformation in the reservoir 11 increases, and the expression power of the reservoir 11 is enhanced,

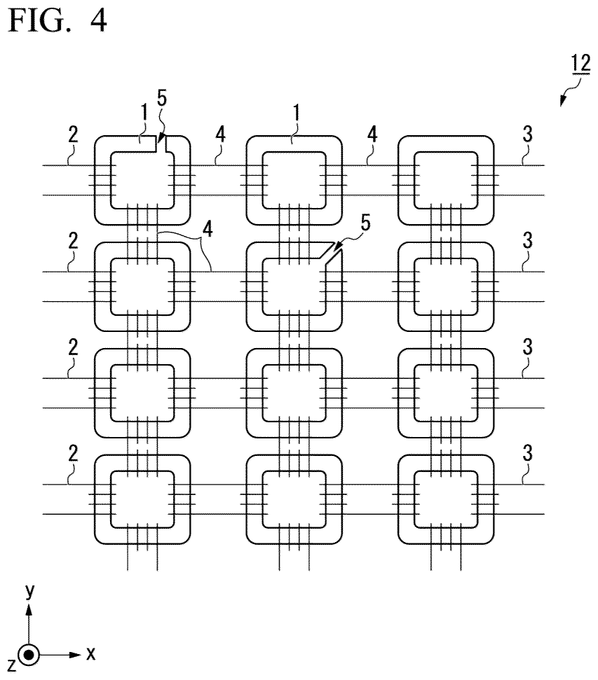

FIG. 4 is a plan view of the reservoir 12 according to a second modified example. In the reservoir 12 shown in FIG. 4, the same configuration as that of the reservoir 10 will not be described.

At least one of the plurality of magnetic circuits 1 has a gap 5 in a part of a magnetic path through which a magnetic flux circulates. The gap 5 reduces an effective permeability of the magnetic circuit 1 and increases an amount of energy that can be stored in the magnetic circuit 1. When the magnetic circuit 1 has the gap 5, the magnetic circuit 1 becomes less likely to be saturated. The magnetic circuit 1 having the gap 5 has a different inductance from a magnetic circuit without the gap 5. When there is a variation in inductance of the magnetic circuit 1, the nonlinearity of signal transformation in the reservoir 12 increases, and the expression power of the reservoir 12 is enhanced.

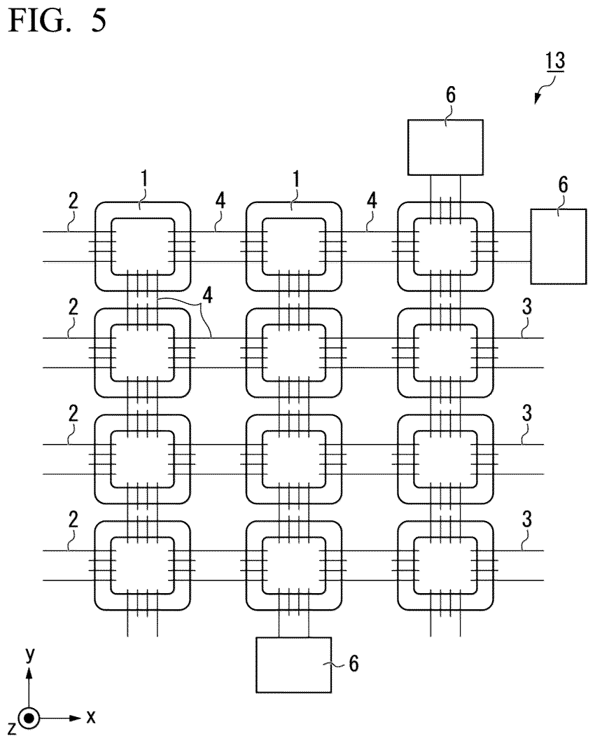

FIG. 5 is a plan view of the reservoir 13 according to a third modified example. In the reservoir 13 shown in FIG. 5, the same configuration as that of the reservoir 10 will not be described.

A load 6 is connected to at least one of the plurality of magnetic circuits. The load 6 is, for example, a linear circuit, a nonlinear circuit, a variable resistance element, or the like. For example, a resistor, a diode, a transistor, and the like may be connected as the load 6.

The load 6 functions as a fixed end of a signal propagating through the connection portion 4 in the reservoir 13. The load 6 affects the propagation of the signal in the reservoir 13 and can adjust the nonlinearity of the reservoir 13.

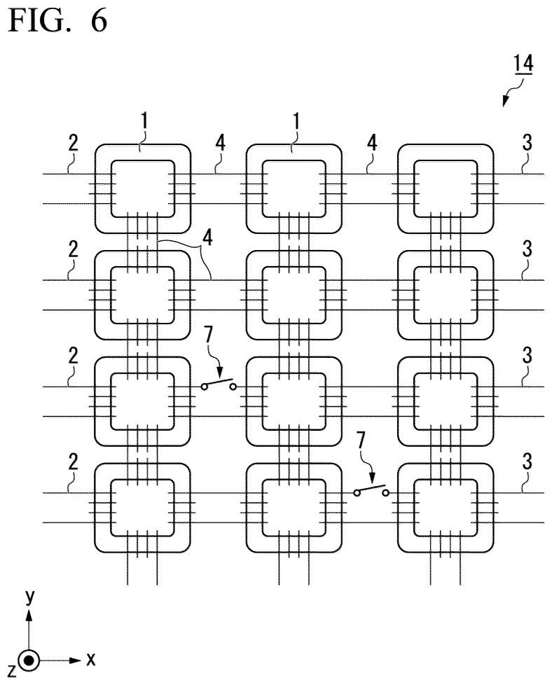

FIG. 6 is a plan view of the reservoir 14 according to a fourth modified example. In the reservoir 14 shown in FIG. 6, the same configuration as that of the reservoir 10 will not be described.

A part of the connection portion 4 of the reservoir 14 has a switch 7 that switches an electrical or magnetic coupling state between at least two magnetic circuits 1.

By switching a connection of the connection portion 4 using the switch 7, the reservoir 14 can change a nonlinear coupling state of the reservoir 14 according to, for example, a task for which an answer is required.

A connection state of the magnetic circuit 1 through the connection portion 4 can be freely designed.

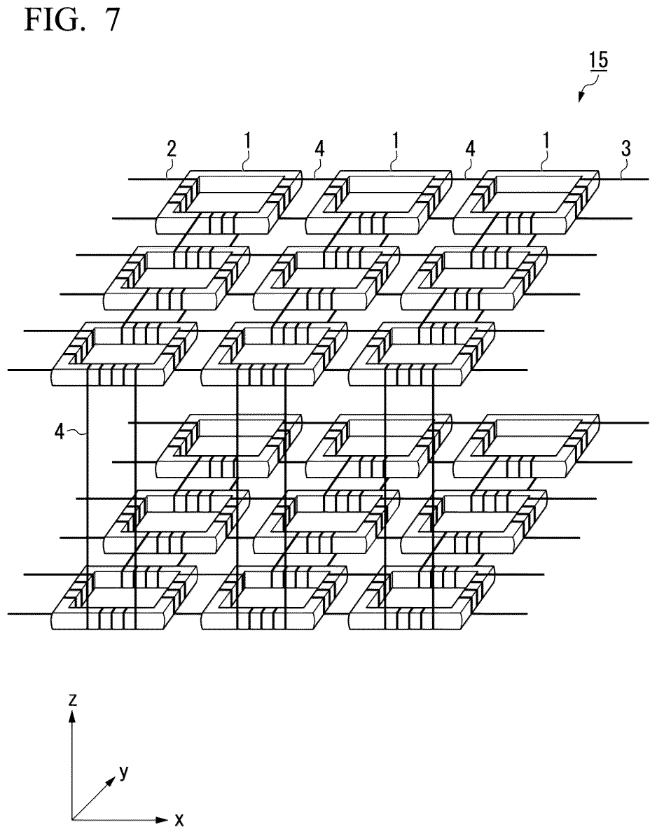

For example, as in the reservoir 15 shown in FIG. 7, the plurality of magnetic circuits 1 may be arranged three-dimensionally through the connection portion 4. The reservoir 15 in which the magnetic circuits 1 are arranged three-dimensionally has high integration.

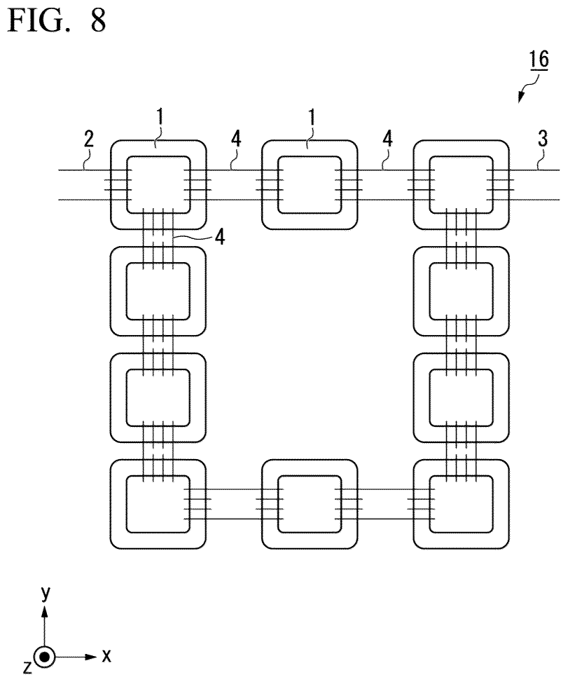

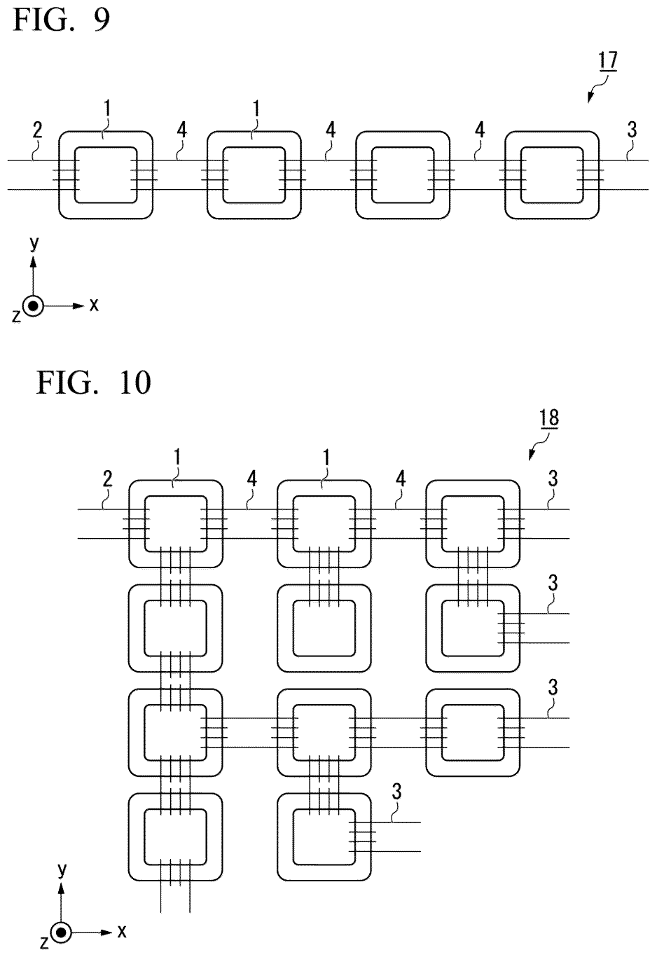

For example, as in the reservoir 16 shown in FIG. 8, a plurality of magnetic circuits 1 may be arranged in a ring shape through the connection portion 4. In addition, as in the reservoir 17 shown in FIG. 9, the plurality of magnetic circuits 1 may be arranged in a line shape through the connection portion 4. Moreover, as in the reservoir 18 shown in FIG. 10, the plurality of magnetic circuits 1 may be arranged in a tree shape through the connection portion 4.

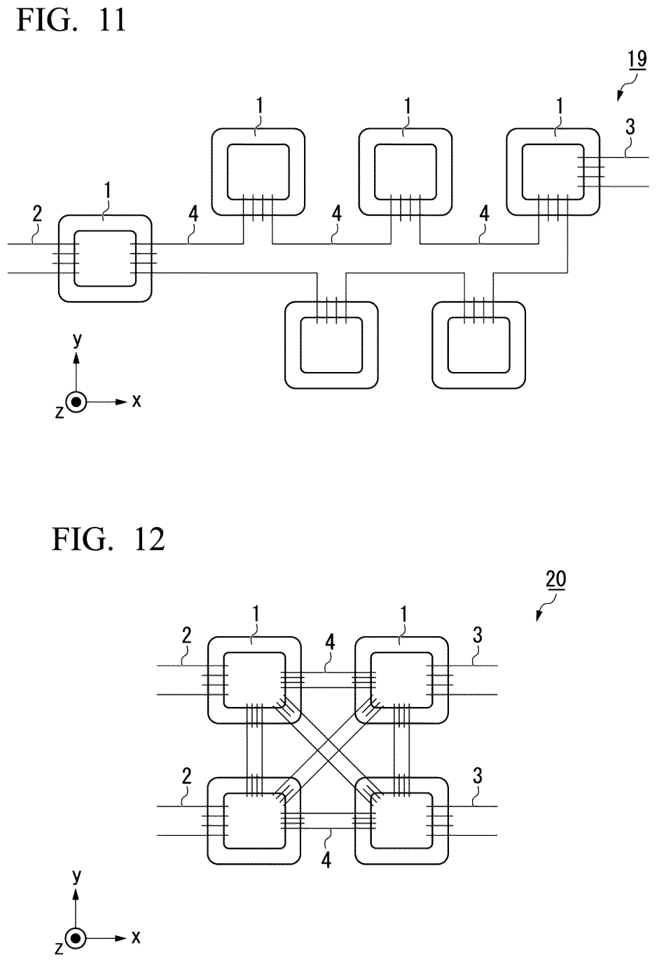

In addition, for example, as in the reservoir 19 shown in FIG. 11, the connection portion 4 may be connected across three or more magnetic circuits 1. Furthermore, for example, as in the reservoir 20 shown in FIG. 12, each magnetic circuit 1 may be connected to all of the different magnetic circuits 1 through the connection portion 4.

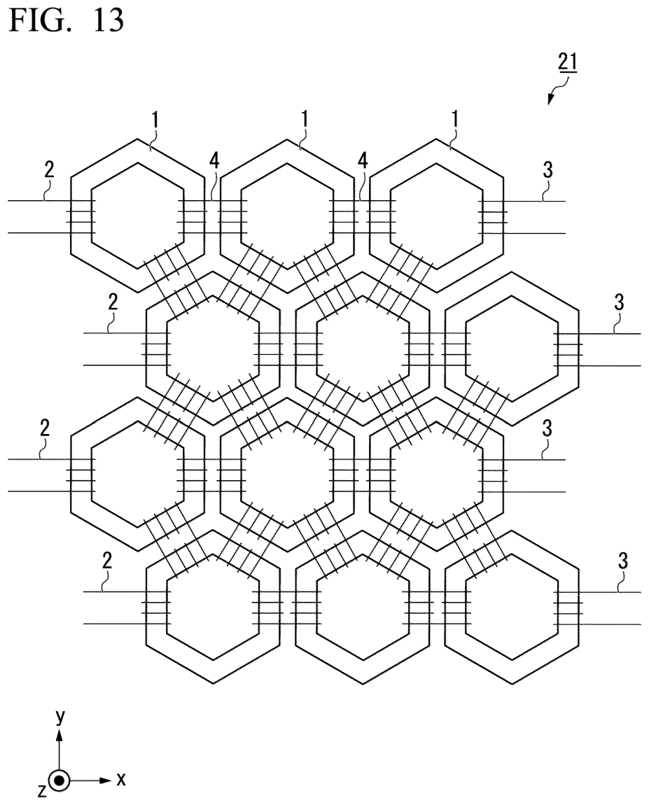

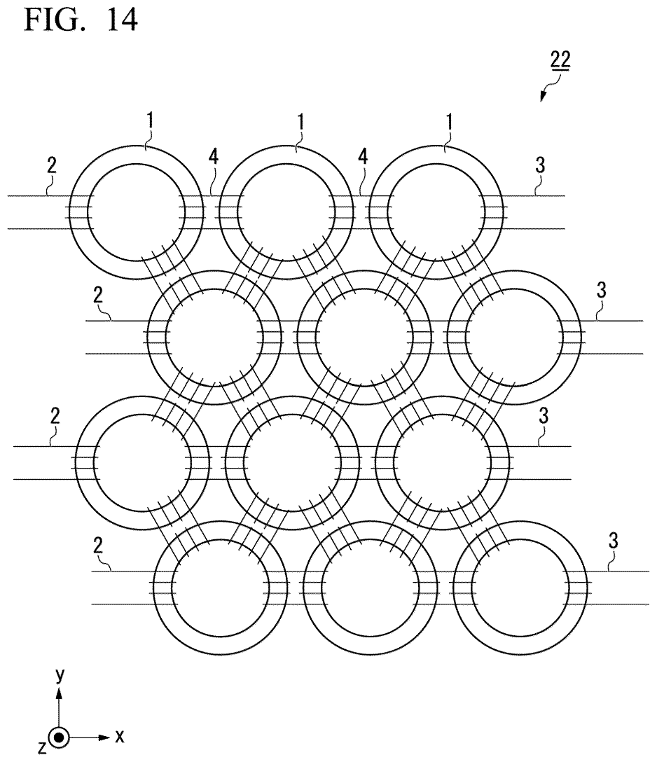

Moreover, a planar shape of each magnetic circuit 1 is not limited to a rectangle, but may be a hexagon like the reservoir 21 shown in FIG. 13, a circle like the reservoir 21 shown in FIG. 14, or other indefinite shape. When the planar shape of the magnetic circuit 1 is a hexagon or circle, an integration of the magnetic circuits 1 can be increased by disposing the magnetic circuits 1 in a hexagonal close-packed manner.

Furthermore, the magnetic circuits 1 are not limited to annular ferromagnetic bodies with one magnetic path through which a magnetic flux circulates, as exemplified so far.

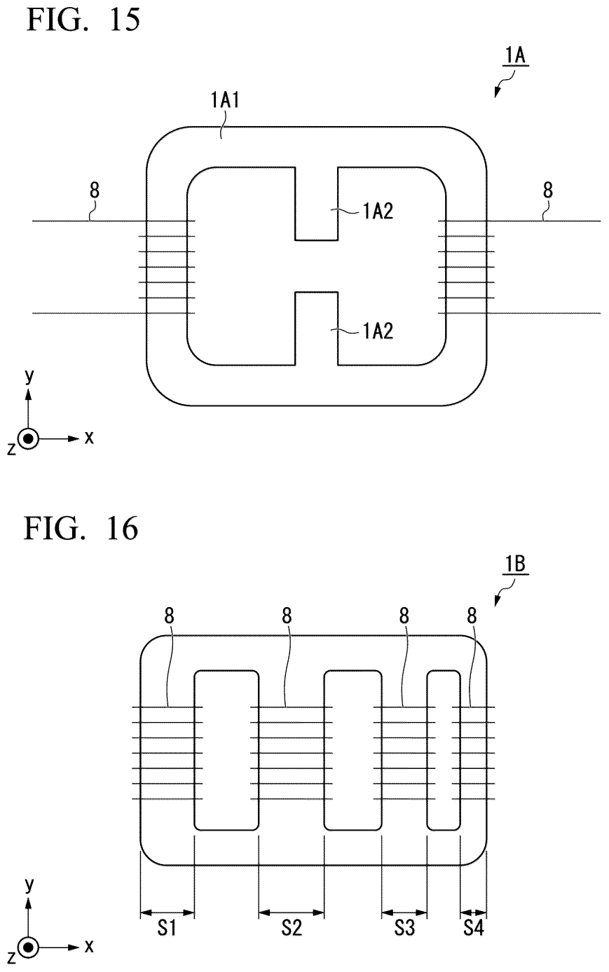

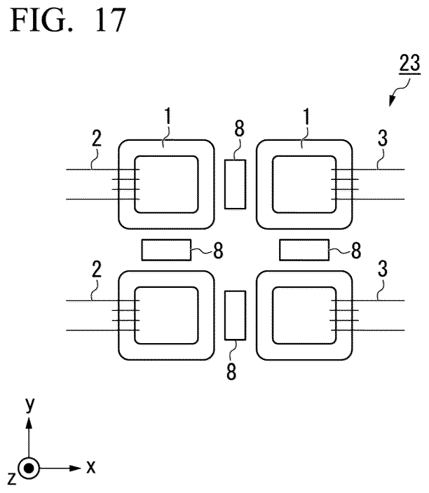

For example, at least a portion of the magnetic circuit 1 may be replaced with the magnetic circuit 1A shown in FIG. 15. The magnetic circuit 1A has a ring-shaped main portion 1A1 and a convex portion 1A2 protruding inward from the main portion. A connection portion 8 is formed in the magnetic circuit 1A. The connection portion 8 corresponds to any one of the input terminal 2, the output terminal 3, and the connection portion 4 described above. The convex portion 1A2 serves as a path for a leakage magnetic flux. When a secondary current increases, the leakage magnetic flux increases and a secondary voltage decreases. The convex portion 1A2 prevents the secondary current from exceeding a certain value.

For example, at least a portion of the magnetic circuit 1 may be replaced with a magnetic circuit 1B shown in FIG. 15. The connection portion 8 is formed in the magnetic circuit 1B. The magnetic circuit 1B has a plurality of magnetic paths through which a magnetic flux circulates. In addition, the cross-sectional areas S1 to S4 of the respective magnetic paths may be different. By changing cross-sectional areas S1 to S4 of each magnetic path, it is possible to perform fine-adjustment on a magnetic flux density and an electromotive force corresponding to the coupling weight wᵢ. When the connection weight wᵢ can be fine-adjusted, the reservoir 10 can be controlled more precisely.

Although an example has been shown so far in which the connection portion 4 is a coil, but the connection portion 4 is not limited to a coil as long as it can electrically or magnetically couple two or more magnetic circuits 1 together.

For example, in the reservoir 23 shown in FIG. 17, the connection portion 9 is a magnet. The magnet transmits an influence of the magnetic field generated in one magnetic circuit 1 to another magnetic circuit 1. The magnet connects magnetically different magnetic circuits 1 together.

Characteristic configurations of the modified example described above may also be combined. For example, the shape of the magnetic circuit 1 and the state of the connection portion 4 in each of the reservoirs 11 to 22 may be varied. In addition, for example, any one of the gap 5, the load 6, and the switch 7 may be added to each of the reservoirs 11 to 22. Moreover, for example, the connection portion 4 of each of the reservoirs 11 to 22 may be replaced with the connection portion 8.

### REFERENCE SIGNS LIST

1, 1A, 1B Magnetic circuit
2 Input terminal
3 Output terminal
4 Connection portion
4A First connection portion
4B Second connection portion
5 Gap
6 Load
7 Switch
8, 9 Connection portion
10, 11, 12, 13, 14, 15, 16, 17, 18, 19, 20, 21, 22, 23, R Reservoir
50, Lᵢₙ Input layer
51 Input source
52 Signal distribution unit
60, Lₒᵤₜ Output layer
61 Arithmetic unit
62 Memory
100 Information processing device
n₁, n₂, n₃ Node
RC Reservoir computing

1. An information processing device comprising:
a plurality of magnetic circuits;
at least one input terminal that is connected to at least one of the plurality of magnetic circuits;
at least one output terminal that is connected to at least one of the plurality of magnetic circuits; and
at least one connection portion that electrically or magnetically couples at least two of the plurality of magnetic circuits.

2. The information processing device according to claim 1,
wherein at least one of the plurality of magnetic circuits has a shape different from the other magnetic circuits.

3. The information processing device according to claim 1,
wherein at least one of the plurality of magnetic circuits has a gap in a portion of a magnetic path through which a magnetic flux circulates.

4. The information processing device according to claim 1,
wherein at least one of the plurality of magnetic circuits is connected to a load.

5. The information processing device according to claim 1,
wherein the connection portion includes a coil wound around two or more different magnetic circuits.

6. The information processing device according to claim 5,
wherein the at least one connection portion is a plurality of connection portions,
the plurality of connection portions include a first connection portion and a second connection portion,
the first connection portion and the second connection portion each include a coil wound around two or more different magnetic circuits, and
the number of turns of a coil constituting the first connection portion is different from the number of turns of a coil constituting the second connection portion.

7. The information processing device according to claim 1,
wherein the connection portion includes a switch that switches an electrical or magnetic coupling state between at least two magnetic circuits.

8. The information processing device according to claim 1,
wherein the plurality of magnetic circuits are arranged three-dimensionally through the connection portion.

9. The information processing device according to claim 1,
wherein the plurality of magnetic circuits are arranged in a ring shape through the connection portion.

10. The information processing device according to claim 1,
wherein the plurality of magnetic circuits are arranged in a line shape through the connection portion.

11. The information processing device according to claim 1,
wherein the plurality of magnetic circuits are arranged in a tree shape through the connection portion.

12. The information processing device according to claim 1,
wherein each of the plurality of magnetic circuits is connected to each other through one connection portion.

13. The information processing device according to claim 1,
wherein each of the plurality of magnetic circuits is connected to all of the different magnetic circuits through the connection portion.

14. The information processing device according to claim 1, further comprising:
an input layer that is connected to the input terminal; and
an output layer that is connected to the output terminal.
